(19) United States
(12) Patent Application Publication
(10) Pub. No.: US 2014/0001931 A1
(43) Pub. Date: Jan. 2, 2014

(54) Light-Weight Frame for Gun Module Remote Control System

(71) Applicants: Justin R. Helton, Fredericksburg, VA (US); Andrew C. Smith, King George, VA (US)

(72) Inventors: Justin R. Helton, Fredericksburg, VA (US); Andrew C. Smith, King George, VA (US)

(73) Assignee: United States Government, as represented by the Secretary of the Navy, Arlington, VA (US)

(21) Appl. No.: 13/535,470

(22) Filed: Jun. 28, 2012

(51) Int. Cl. H05K 7/18; H05K 5/02

(52) U.S. Cl. 312/223.1

(57) ABSTRACT

A modular frame is provided for containing electronic components within a replaceable mission module for installation aboard ship. The frame includes a plurality of metal tubes having rectangular cross-section, a plurality of sheet-metal panels, and a plurality of fasteners for connecting together the tubes and panels. The frame assembles as a rectangular base platform, a lower portion, a mezzanine level, and an interface level. The base platform includes horizontally arranged tubes. The lower portion has vertical tubes attaching to the horizontal tubes on the base platform. The mezzanine level has a horizontal panel and horizontal tubes connecting together atop the lower portion. The upper portion has vertical tubes attaching to the horizontal tubes of the mezzanine level. The interface level has horizontal tubes connecting together atop the vertical tubes of the upper portion.

### STATEMENT OF GOVERNMENT INTEREST

The invention described was made in the performance of official duties by one or more employees of the Department of the Navy, and thus, the invention herein may be manufactured, used or licensed by or for the Government of the United States of America for governmental purposes without the payment of any royalties thereon or therefor.

### BACKGROUND

The invention relates generally to modular frames for ship-board control systems. In particular, the invention relates to a light-weight frame for a gun control system used aboard a Littoral Combat Ship (LCS) intended for the United States Navy to provide close shore fire support. The LCS design enables installation of integrated mission modules for operation in particular mission types and subsequent removal for refurbishment or replacement.

The lead ships for these classes are the steel planing monohull U.S.S. Freedom (LCS-1) designed by Lockheed Martin, and the aluminum trimaran U.S.S. Independence (LCS-2) contracted through Austal of Alabama. Both LCS classes can be reconfigured with interchangeable weapons modules for select plug-and-fight missions. Follow-on ships in the Freedom-class include U.S.S. Fort Worth (LCS-3), U.S.S. Milwaukee (LCS-5), U.S.S. Detroit (LCS-7), U.S.S. Little Rock (LCS-9) and U.S.S. Sioux City (LCS-11). Follow-on ships in the Independence-class include U.S.S. Coronado (LCS-4), U.S.S. Jackson (LCS-6), U.S.S. Montgomery (LCS-8) U.S.S. Gabrielle Gifford (LCS-10) and U.S.S. Omaha (LCS-12). The LCS classes will eventually replace the U.S.S. Oliver Hazard Perry-class frigates (FFG-7).

The Mk-50 Gun Mission Module (GMM), as an example for the surface warfare module package, includes two turret-mounted, axis-stabilized chain guns that can fire up to 200 rounds per minute of 30×173 mm ammunition, and can hold 800 rounds. Uniformed Navy personnel operate in highly confined spaces, including below deck. A gun module remote control system (GMRCS) is contained in a housing below deck installed within the GMM.

### SUMMARY

Conventional ship-board frames for electronic systems yield disadvantages addressed by various exemplary embodiments of the present invention. In particular, a modular frame is provided for containing electronic components within a replaceable mission module for installation aboard ship. The frame includes a plurality of metal tubes having rectangular cross-section, a plurality of sheet-metal panels, and a plurality of fasteners for connecting together the tubes and panels.

In various exemplary embodiments, the frame assembles as a rectangular base platform, a lower portion, a mezzanine level, and an interface level. The base platform has a first horizontal parallel pair of tubes connected together by a first horizontal plurality of tubes. The lower portion has first two vertical pairs of tubes, each pair disposed adjacent opposing ends of and attaching to a corresponding tube of the first horizontal pair of tubes on the base platform. The mezzanine level has a horizontal panel and first two horizontal pairs of tubes connecting together atop the first two vertical pairs of tubes of the lower portion, wherein first bevel pluralities of tubes connect between the base platform and the mezzanine level. The upper portion has second two vertical pairs of tubes attaching to the first two horizontal pairs of tubes of the mezzanine level. The interface level has second two horizontal pairs of tubes connecting together atop the second two vertical pairs of tubes of the upper portion, wherein second bevel pluralities of tubes connect between the mezzanine level and the interface level.

In alternate embodiments, the frame further includes an instrument section having third bevel pluralities of tubes attaching atop said interface level to support an instrument panel. In various embodiments, the metal from which are formed the tubes and panels constitutes aluminum.

### BRIEF DESCRIPTION OF THE DRAWINGS

These and various other features and aspects of various exemplary embodiments will be readily understood with reference to the following detailed description taken in conjunction with the accompanying drawings, in which like or similar numbers are used throughout, and in which:

FIG. 1 is a perspective view of a conventional housing for a shipboard gun control system;

FIG. 2 is a perspective view of an exemplary cabinet; and

FIG. 3 is an isometric view of an exemplary frame that provides structure for the cabinet.

### DETAILED DESCRIPTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and many changes may be made without departing from the spirit or scope of the present invention. The following detailed description is, therefore, not to be taken in a limiting sense, and the scope of the present invention is defined only by the appended claims.

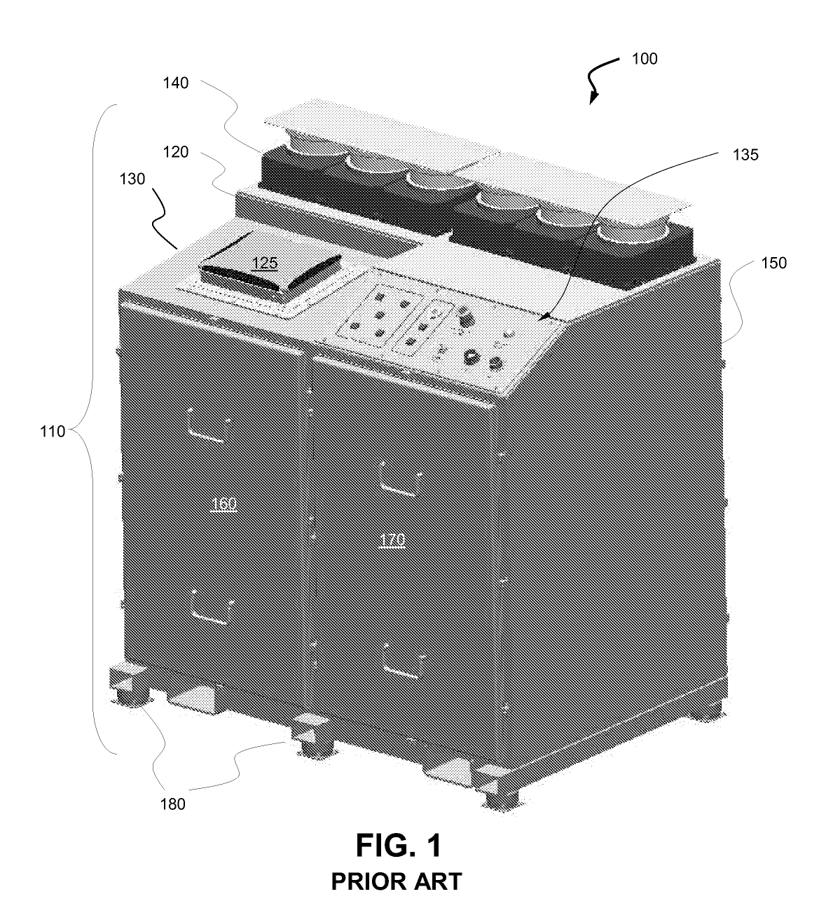

FIG. 1 shows a perspective view 100 of conventional housing 110 for a shipboard gun control system. This housing represents a second version of an engineering design module (EDM) for the GMRCS. This conventional housing 110 requires active cooling for electronic components. This design cannot be serviced without loss of its environmental seal. The EDM2 has a structural weight of about 285 lbm.

The conventional housing 110 includes an upper portion 120 equipped with a Toughbook® laptop 125 disposed onto a starboard upper-level platform 130, with an adjacent port upper-level platform 135 for control switches. Air-conditioning equipment 140 is disposed atop the upper portion 120. A cabinet 150 below the upper portion 120 includes a starboard drawer 160 and a port panel drawer 170. A base stand 180 provides a frame with legs to support the cabinet 150 and ancillary equipment.

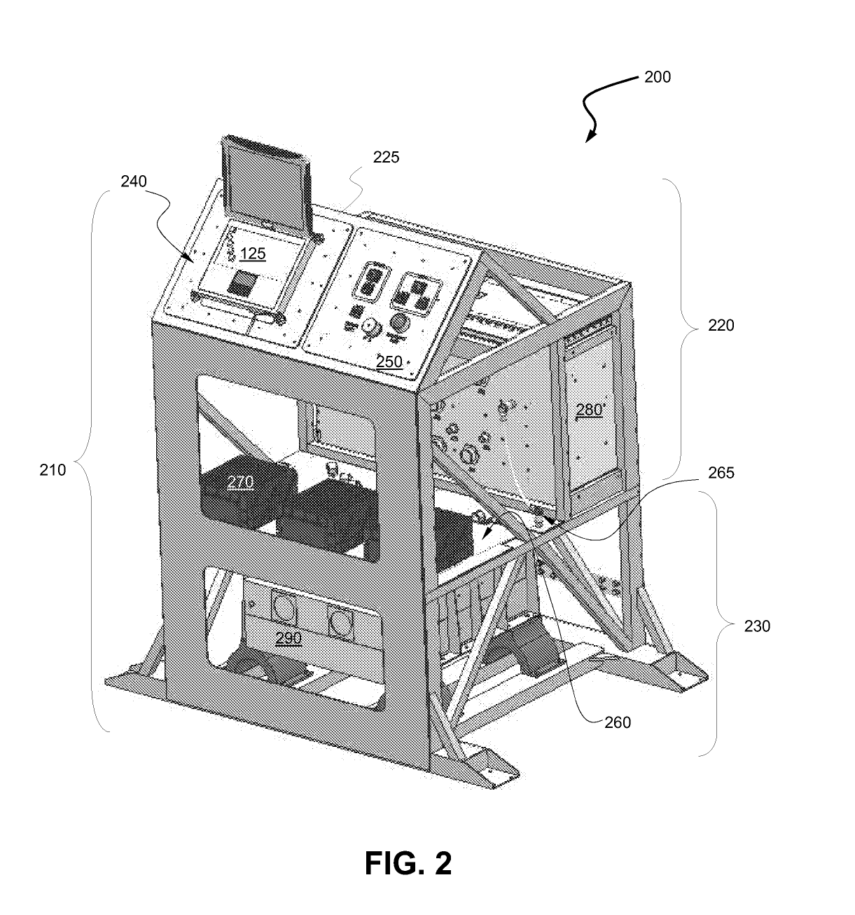

FIG. 2 shows a perspective view 200 of an exemplary operational housing or open cabinet as a third EDM 210. By comparison to the conventional version, the EDM3 210 has a light-weight open GMRCS frame that enables passive cooling. Self-contained and closed subsystems can be interfaced and bolted into position and removed without comprising other system components. The open EDM3 210 has a structural weight of about 156 lbm. The EDM3 210 comprises primarily aluminum tubing (6063-T6) with either square or rectangular cross-section. Alternatively, tubing could be produced from steel or other structurally appropriate metal.

The EDM3 210 includes an upper module 220 having an instrument panel 225 oriented 45° from horizontal within an A-frame gable, and a lower module 230. Starboard and port panels 240 and 250 provide operator convenient access to monitoring and control interfaces. For example, the laptop 125 can be disposed on the starboard panel 240. A mezzanine platform 260 disposed between the modules 220 and 230 supports a ground boss 265, as well as a triplet of rugged personal computers 270 and a switchboard 280. The upper module 220 supports both the computers 270 and the switchboard 260. The lower module 230 supports a universal power supply (UPS) 290. The computers 270 are mounted on unpainted surfaces to the EDM3 210, which serves as a thermal heat-sink. The switchboard 280 forms an enclosure that houses the majority of the commercial-off-the-shelf (COTS) electronics, especially those lacking moisture resistance. The switchboard 280 provides cable and wire connections into and out of the electronics therein. The UPS 290 includes a shock-mounted battery and transformer to convert alternating current (AC) to direct current (DC), which is used for the GMRCS sub-assembly.

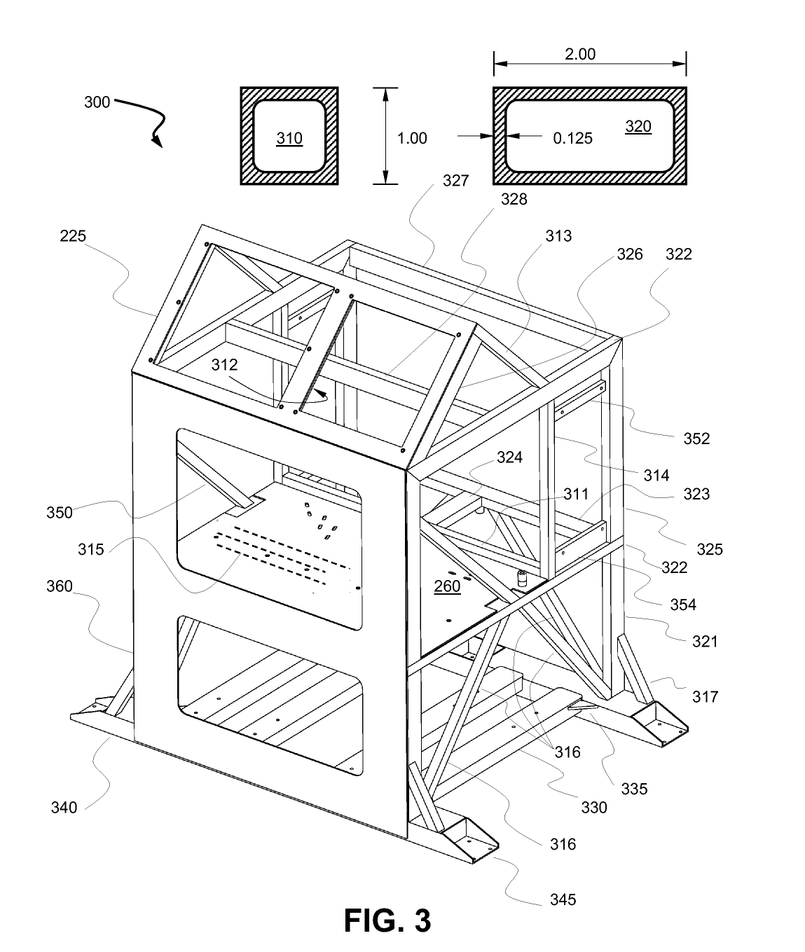

FIG. 3 shows an isometric view 300 of an exemplary frame that provides structure for the cabinet as shown in view 200. Both upper and lower frames 220 and 230 incorporate square and rectangular cross-section aluminum tubes connected together. A cross-section of the square tube 310 shows these bars as one inch (1″) on each side and ⅛″ in thickness. For purposes of disclosure, these tubes can be generalized as having rectangular cross-section. The square tubes include three horizontal beams 311, a bevel gable member 312, three pairs of upper bevel gables 313, a pair of upper vertical posts 314, a pair of horizontal runners 315 (one of which shown underneath the platform 260, three pairs of lower bevel gables 316, and two pairs of foot rests 317.

A cross-section of the rectangular tube 320 shows these bars as one and two inches (1″, 2″) on adjacent sides and one-eighth inch (⅛″) in thickness. The rectangular tubes include two pairs of lower vertical posts 321, two pairs of horizontal beams 322, a pair of horizontal beams 323, a horizontal beam 324, two pairs of upper vertical posts 325, a pair of bevel gables 326, a pair of upper horizontal beams 327, and a header horizontal beam 328. Four floor beam arms 330 can be arranged in parallel and maintained in alignment by two pairs of gussets 335 onto attaching floor beam legs 340 that flank the beam arms 330. The beam legs 340 terminate in feet 345 for bolting to a floor. The legs 340 and arms 330 connect together to form the base stand of the EDM3 210.

The instrument panel 225 attaches to the bevel gables 326 and provides the mount surfaces for the panels 230 and 240. A pair of bevel cross-bars 350 provides shear support for the posts 325. Opposite pairs of upper and lower barrier flanges 352 and 354 prevent the switchboard 280 from sliding out of position behind the computers 270. A front panel 360 bolts to the vertical posts 321 and 325 and the horizontal beams 323 and 327 to provide shear resistance for the upper and lower frames 210 and 220.

In summary, the frame assembles as a rectangular base platform, a lower portion, a mezzanine level, and an interface level. The base platform has a first horizontal parallel pair of tubes as legs 340 connected together by a first horizontal plurality of tubes as arms 330. The lower portion 230 includes first two vertical pairs of tubes as posts 321, each pair disposed adjacent opposing ends of and attaching to a corresponding tube of the legs 340 on the base platform. The mezzanine level has a horizontal panel 260 and first two horizontal pairs of tubes as beams 322 and 323 connecting together atop the posts 321 of the lower portion 230. Additionally, first bevel pluralities of tubes as gables 316 connect between the base platform and the mezzanine level. The upper portion 220 includes second two vertical pairs of tubes 325 attaching to the beams 322 of the mezzanine level. The interface level has second two horizontal pairs of tubes as beams 322 and 327 connecting together atop the posts tubes 325 of the upper portion 220, wherein second bevel pluralities of tubes as gables 350 connect between the mezzanine level and the interface level.

Select components, such as the platform 260 and the arms 330 include mount holes for receiving fasteners. Such fasteners can include threaded nuts and bolts to facilitate disassembly, or alternately rivets for greater permanence. The panels 225 and 360, platform 260, gussets 335, and flanges 352 and 354 can comprise sheet metal, such as aluminum. Artisans of ordinary skill will recognize that variations of this design, including selection of tube cross-section for particular frame components, as well as dispositional alignments of interfaces and orientations of structural members, can be implemented without departing from the scope of the invention.

For the exemplary LCS GMM configuration shown, the frame exhibits the following dimensions. The front panel 360 has a length of 32.625 inches and a height of 39.25 inches. The feet 345 on the lower structure 220 extend 47.75 inches. The depth of the frames is 33.13 inches. The bevel A-frame for the front panels 240 and 250 extend 11.11 inches above the front panel 360 angled at 45° from the horizontal beams 322.

The light-weight open GMRCS frame for Gun Mission Module (GMM) was developed to house multiple enclosed sub-systems in the EDM3 210 that comprise the GMRCS sub-assembly in the Mk-50 GMM. The frame maintains structural integrity in response to expected vibration and shock conditions. The exemplary frame disposes and connects the GMRCS subsystem in the Mk-50 GMM in a non-air-conditioned space aboard ship, and renders possible the GMRCS subsystem to be subdivided into multiple line-replaceable-units (LRUs) in a larger, modular system. The conventional EDM2 110 is a ruggedized 19-inch rack-based system with the same functionality, but lacks the option of replacing smaller LRUs without compromising the environmental seal on the entire cabinet and is heavier than the exemplary EDM3 210.

The exemplary frame provides fastening interfaces for the uninterruptible power supply, switchboard, button bezel, maintenance station, and computational sub-components. The exemplary frame is disposed onto the Electrical Berth of the GMM and visually presents sub-assemblies accessed by operational personnel at an easy-to-see height and angle. The exemplary frame contains integrated cable routing and chassis grounding connections. The EDM3 210 configuration can be applied to a complex, modular system in unconditioned (i.e., ambient non-airconditioned) spaces where ruggedness and ease of maintenance constitute design objectives. The exemplary frame arrangement is a component in the baseline of the EDM3 210 of the LCS GMM.

The advantage of these exemplary embodiments includes increased modularity and ability to use small replaceable sub-systems. The exemplary frame can be assembled from standard square and rectangular aluminum tubing, fasteners, such as nut-and-bolt combinations, and flat panels. This would enables the component to be simply disconnected, unbolted and replaced in lieu of more involved operations (e.g., wire cutting). The exemplary frame contains integrated cable routing and grounding connections for each component that comprises the entire assembly. The exemplary frame also reduces system weight by 45% as well as increasing mechanical strength. Although conventional ruggedized computer cabinets exist, no conventional COTS arrangement can provide functionality needed by the GMRCS sub-system while providing modular replacement of LRUs in an unconditioned space. The exemplary frame can be expected to be used for related LCS mission modules.

While certain features of the embodiments of the invention have been illustrated as described herein, many modifications, substitutions, changes and equivalents will now occur to those skilled in the art. It is, therefore, to be understood that the appended claims are intended to cover all such modifications and changes as fall within the true spirit of the embodiments.

What is claimed is:

1. A modular frame for containing electronic components within a replaceable mission module for installation aboard ship, said frame comprising
a plurality of metal tubes having rectangular cross-section;
a plurality of sheet-metal panels, and
a plurality of fasteners for connecting together said tubes and panels, wherein said frame assembles as:
a rectangular base platform having a first horizontal parallel pair of tubes connected together by a first horizontal plurality of tubes;
a lower portion having first two vertical pairs of tubes, each pair disposed adjacent opposing ends of and attaching to a corresponding tube of said first horizontal pair of tubes on said base platform;
a mezzanine level having a horizontal panel and first two horizontal pairs of tubes connecting together atop said first two vertical pairs of tubes of said lower portion, wherein first bevel pluralities of tubes connect between said base platform and said mezzanine level;
an upper portion having second two vertical pairs of tubes attaching to said first two horizontal pairs of tubes of said mezzanine level; and
an interface level having second two horizontal pairs of tubes connecting together atop said second two vertical pairs of tubes of said upper portion, wherein second bevel pluralities of tubes connect between said mezzanine level and said interface level.

2. The frame according to claim 1, further comprising:
an instrument section having third bevel pluralities of tubes attaching atop said interface level to support an instrument panel.

3. The frame according to claim 1, wherein said metal tubes comprise aluminum.
